(19) United States
(12) Patent Application Publication
(10) Pub. No.: US 2022/0355344 A1
(43) Pub. Date: Nov. 10, 2022

(54) APPARATUS AND METHOD FOR TREATING SUBSTRATE

(71) Applicant: SEMES CO., LTD., Chungcheongnam-do (KR)

(72) Inventors: Hyun Seok Choi, Gyeonggi-do (KR); Ki Young Kwak, Gyeonggi-do (KR); Dong Hee Son, Gyeonggi-do (KR); Jong Hwan Park, Gyeonggi-do (KR); Jong Jin Jung, Seoul (KR)

(21) Appl. No.: 17/732,691

(22) Filed: Apr. 29, 2022

(30) Foreign Application Priority Data
May 4, 2021 (KR) 10-2021-0057914

(51) Int. Cl. B08B 3/02; G03F 7/42

(52) U.S. Cl. CPC B08B 3/022; G03F 7/422

(57) ABSTRACT

An apparatus and method for treating a substrate that implement a recipe capable of increasing an absorption amount of metal ions to the substrate are provided. The method for treating the substrate includes: ejecting a substrate treating liquid onto the substrate; rotating the substrate at a first low-speed; and when the ejecting of the substrate treating liquid has been finished, drying the substrate.

### CROSS-REFERENCE TO RELATED APPLICATION

This application claims priority from Korean Patent Application No. 10-2021-0057914 filed on May 4, 2021 in the Korean Intellectual Property Office, and all the benefits accruing therefrom under 35 U.S.C. 119, the contents of which in its entirety are herein incorporated by reference.

### BACKGROUND

### Technical Field

The present disclosure relates to an apparatus and method for treating a substrate. More specifically, the present disclosure relates to an apparatus and method for cleaning a substrate.

### Description of Related Art

A semiconductor device manufacturing process may be continuously performed within a semiconductor device manufacturing facility, and may be divided into a front-end process and a post-end process. The semiconductor device manufacturing facility may be installed in a space defined as a fab to manufacture a semiconductor device.

The front-end process refers to a process that completes a chip by forming a circuit pattern on a wafer. The front-end process may include a deposition process that forms a thin film on the wafer, a photolithography process that transfers a photoresist onto the thin film using a photomask, an etching process that selectively removes a unnecessary portion using chemical substance or reactive gas to form a desired circuit pattern on the wafer, an ashing process that removes the photoresist remaining after the etching, an ion implantation process that implants ions into a portion connected to the circuit pattern to achieve characteristics of an electronic device, and a cleaning process that removes contaminants from the wafer, etc.

The post-end process refers to a process of evaluating performance of the product completed via the front-end process. The post-end process may include a first inspection process that selects good products and defects by inspecting an operation of each chip on the wafer, a package process of cutting and dividing each chip to achieve a product form using dicing, die bonding, wire bonding, molding, marking, etc., a final inspection process to inspect product characteristics and reliability via electrical property inspection, and burn-in inspection, etc.

### SUMMARY

Recently, defects that were invisible in the past during a wafer process are visible as the process has been converted to a microprocess. Thus, it is necessary to analyze causes of the defects. For example, when a process operator wants to identify whether or not metal ions are detected on a surface of a wafer, a conventional mass production recipe has a disadvantage that a residence time of chemical and metal ions in the chemical on the wafer is short and thus an absorption amount of the metal ions on the wafer is lowered.

A purpose of the present disclosure is configured to provide an apparatus and method for treating a substrate that implements a recipe capable of increasing the absorption amount of the metal ions on a substrate.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, the signal will be easily understood that the purposes and advantages according to the present disclosure may be realized using means shown in the claims and combinations thereof.

One aspect of the present disclosure to achieve the purpose provides a method for treating a substrate, the method comprising: ejecting a substrate treating liquid onto the substrate; rotating the substrate at a first low-speed; and when the ejecting of the substrate treating liquid has been finished, drying the substrate.

In one implementation of the method, the method for treating the substrate is performed when inspecting the substrate treating liquid, and/or inspecting a nozzle for ejecting the substrate treating liquid.

In one implementation of the method, the method further comprises rotating the substrate at a second low-speed, wherein rotating the substrate at the second low-speed is performed simultaneously with or before or after the drying of the substate.

In one implementation of the method, the first low-speed is set to a speed at which the substrate treating liquid is not bounced off from the substrate.

In one implementation of the method, the first low-speed is lower than a first reference speed.

In one implementation of the method, the first reference speed is a rotation speed when the substrate is generally treated.

In one implementation of the method, the first low-speed is constant while the substrate treating liquid is ejected.

In one implementation of the method, the drying of the substrate includes naturally drying the substrate.

In one implementation of the method, the drying of the substrate includes drying the substrate while the substrate does not rotate.

In one implementation of the method, the ejecting of the substrate treating liquid is performed simultaneously with the rotating of the substate at the first low-speed, or is performed before the rotating the substrate at the first low-speed.

In one implementation of the method, the second low-speed is equal to or lower than the first low-speed.

In one implementation of the method, the first low-speed is 200 RPM.

In one implementation of the method, the first low-speed varies depending on viscosity of the substrate treating liquid.

In one implementation of the method, the method further comprises: when the substrate has been dried, determining whether metal ions are detected on the substrate; and inspecting whether a defect occurs in a nozzle for ejecting the substrate treating liquid and/or the substrate treating liquid is deteriorated, based on the determination result related to the metal ions.

In one implementation of the method, the inspecting includes determining that when the metal ions are detected on the substrate, the substrate treating liquid has been deteriorated and/or the defect has occurred in the nozzle.

Another aspect of the present disclosure to achieve the purpose provides a method for treating a substrate, the method comprising: ejecting a substrate treating liquid onto the substrate; rotating the substrate at a first low-speed; when the ejecting of the substrate treating liquid has been finished, drying the substrate; and rotating the substrate at a second low-speed; wherein each of the first low-speed and the second low-speed is set to a speed at which the substrate treating liquid is not bounced off from the substrate.

Still another aspect of the present disclosure to achieve the purpose provides an apparatus for treating a substrate, the apparatus comprising: a substrate support module for supporting the substrate; and a spray module for ejecting a substrate treating liquid onto the substrate, wherein the substrate support module is configured to rotate the substrate at a first low-speed when the spray module ejects the substrate treating liquid onto the substrate; wherein the apparatus is configured to dry the substrate when the ejecting of the substrate treating liquid has been finished.

In one implementation of the apparatus, the substrate support module is configured to rotate the substrate at the first low-speed when the substrate treating liquid, and/or a nozzle for ejecting the substrate treating liquid is inspected.

In one implementation of the apparatus, the substrate support module is configured not to rotate the substrate or to rotate the substrate at a second low-speed when the apparatus dries the substrate.

In one implementation of the apparatus, the second low-speed is lower than or equal to the first low-speed.

Specific details of other embodiments are included in the detailed description and drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is a diagram schematically illustrating an internal configuration of a substrate treating system according to an embodiment of the present disclosure;

FIG. 2 is a diagram schematically illustrating an internal structure of an apparatus for treating a substrate constituting a substrate treating system according to an embodiment of the present disclosure;

FIG. 3 is a flowchart sequentially illustrating a method for treating a substrate using an apparatus for treating a substrate according to an embodiment of the present disclosure;

FIG. 4 is a first illustrative diagram for illustrating a method for treating a substrate according to an embodiment of the present disclosure;

FIG. 5 is a second illustrative diagram for illustrating a method for treating a substrate according to an embodiment of the present disclosure;

FIG. 6 is an illustrative diagram for illustrating a difference between a conventional recipe and a prevent recipe according to the present disclosure; and

FIG. 7 is a flowchart for sequentially illustrating a method for treating a substrate after drying of the substrate.

### DETAILED DESCRIPTIONS

Advantages and features of the present disclosure, and how to achieve them will become apparent with reference to the embodiments described below in detail in conjunction with the accompanying drawings. However, the present disclosure is not limited to the embodiments as disclosed below, but will be implemented in a variety of different forms. Only these embodiments make the present disclosure complete, and are constructed to fully inform those having common knowledge in the technical field to which the present disclosure belongs of a scope of the disclosure. The scope of the present disclosure is only defined by the scope of the claims.

A shape, a size, a ratio, an angle, a number, etc. disclosed in the drawings for illustrating embodiments of the present disclosure are exemplary, and the present disclosure is not limited thereto. The same reference numerals refer to the same elements herein. Further, in describing the present disclosure, when it is determined that a detailed description of a related known element may unnecessarily obscure gist of the present disclosure, the detailed description thereof will be omitted. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of the various embodiments of the present disclosure may be partially or entirely combined with each other, and may be technically associated with each other or operate with each other. The embodiments may be implemented independently of each other and may be implemented together in an association relationship. Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure relates to an apparatus for treating a substrate that executes a recipe capable of increasing an absorption amount of metal ions on a substrate, for example, a wafer, and to a substrate treating system having the same. In particular, the present disclosure relates to an apparatus for treating a substrate that executes a recipe capable of increasing the absorption amount of the metal ions to the substrate when it is desired to identify whether or not the metal ions are detected on a surface of the substrate, and to a substrate treating system having the same.

Hereinafter, the present disclosure will be described in detail with reference to drawings and the like.

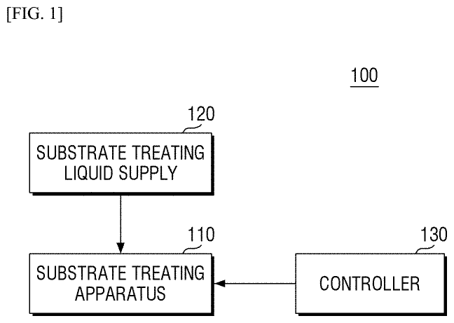

FIG. 1 is a diagram schematically illustrating an internal configuration of a substrate treating system according to an embodiment of the present disclosure.

According to FIG. 1, a substrate treating system 100 may be configured to include an apparatus 110 for treating a substrate, a substrate treating liquid supply 120, and a controller 130.

The apparatus 110 for treating a substrate is configured to treat a substrate using a chemical liquid. The apparatus 110 for treating the substrate may be implemented as a cleaning process chamber that cleans the substrate using the chemical liquid.

The chemical liquid may be a liquid substance, for example, an organic solvent, or a gaseous substance. The chemical liquid may include a substance which is highly volatile and generates a large amount of fumes or has long time residence due to high viscosity. The chemical liquid may include, for example, a substance containing IPA (Iso-Propyl Alcohol), a substance containing sulfuric acid (for example, SPM containing sulfuric acid and hydrogen peroxide), a substance containing ammonia water (for example, SC-1(H₂O₂+NH₄OH)), a substance containing hydrofluoric acid (for example, DHF (Diluted Hydrogen Fluoride), a substance containing phosphoric acid, etc. Hereinafter, these chemical liquids used to treat the substrate will be defined as a substrate treating liquid.

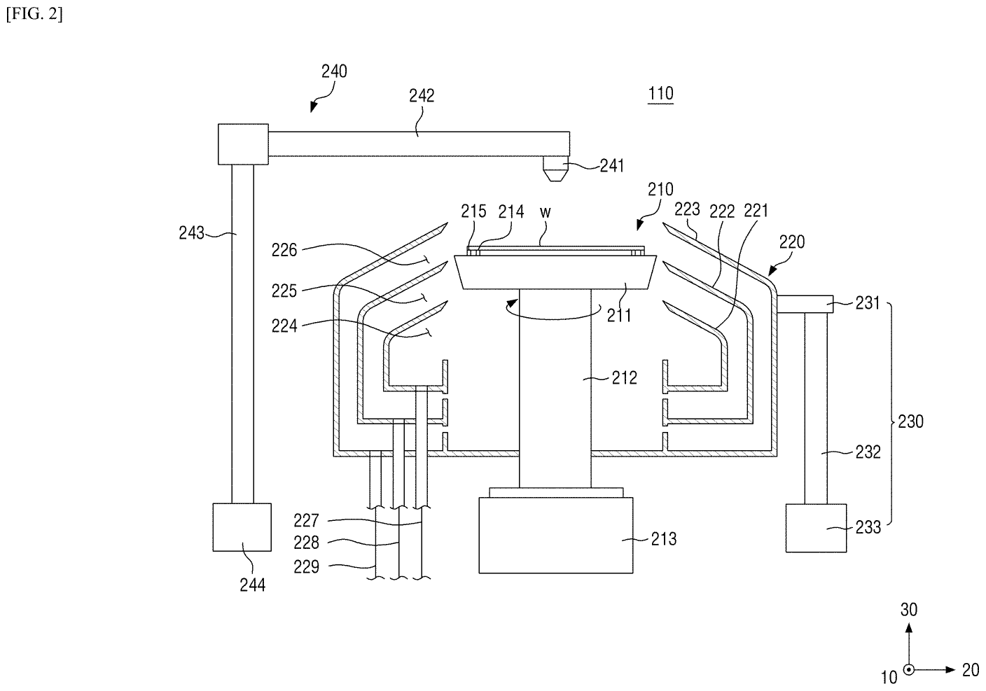

In one example, when the apparatus 110 for treating the substrate is implemented as a cleaning process chamber, the apparatus 110 may be configured to include a substrate support module 210, a treating liquid collection module 220, a lift module 230 and a spray module 240 as shown in FIG. 2. c

FIG. 2 is a diagram schematically illustrating an internal structure of an apparatus for treating a substrate constituting a substrate treating system according to an embodiment of the present disclosure. For following description, reference to FIG. 2 will be made.

The substrate support module 210 is configured to support a substrate W. The substrate support module 210 may rotate the substrate W around a third direction 30 perpendicular to a first direction 10 and a second direction 20 when treating the substrate W. The substrate support module 210 may be disposed inside the treating liquid collection module 220 so as to collect the substrate treating liquid used when treating the substrate W.

The substrate support module 210 may be configured to include a spin head 211, a rotation shaft 212, a rotation driver 213, a support pin 214 and a guide pin 215.

The spin head 211 rotates around the third direction 30 around which the rotation shaft 212 rotates. The spin head 211 may be configured to have the same shape as that of the substrate W. However, the present embodiment is not limited thereto. The spin head 211 may be configured to have a shape different from that of the substrate W.

The rotation shaft 212 generates rotational force using energy provided from the rotation driver 213. The rotation shaft 212 is coupled to each of the rotation driver 213 and the spin head 211 to transmit the rotational force from the rotation driver 213 to the spin head 211. The spin head 211 rotates along the rotation of the rotation shaft 212. In this case, the substrate W seated on the spin head 211 may rotate together with the spin head 211.

The support pin 214 and the guide pin 215 are configured for positioning and fixing the substrate W on the spin head 211. For this purpose, the support pin 214 is disposed on the spin head 211 so as to support a bottom face of the substrate W, and the guide pin 215 is disposed on the spin head 211 so as to supports a side face of the substrate W. A plurality of support pins 214 and guide pins 215 may be installed on the spin head 211.

The support pin 214 may be configured to generally have an annular ring shape. Thus, the support pin 214 may support the bottom face of the substrate W so that the substrate W may be spaced, by a certain distance, from a top of the spin head 211.

The guide pin 215 may be embodied as a chucking pin which may support the substrate W so that the substrate W does not disengage from its original position when the spin head 211 rotates.

In one example, a back nozzle (not shown) may also be installed on the top face of the spin head 211. The back nozzle is configured for cleaning the bottom face of the substrate W. This back nozzle may be installed at a center of the top face of the spin head 211, and may spray the substrate treating liquid to the bottom face of the substrate W.

The treating liquid collection module 220 is configured to collect the substrate treating liquid used to treat the substrate W. The treating liquid collection module 220 may be installed to surround the substrate support module 210, thereby providing a space in which the treating process for the substrate W is performed.

After the substrate W is seated on and fixed to the substrate support module 210, and when the substrate starts to rotate under rotation of the substrate support module 210, the spray module 240 may spray the substrate treating liquid onto the substrate W under control of the controller 130. Then, the substrate treating liquid ejected onto the substrate W due to a centrifugal force generated under the rotational force of the substrate support module 210 may be dispersed in a direction toward the treating liquid collection module 220. In this case, the treating liquid collection module 220 may collect the substrate treating liquid through an inlet (i.e., a first opening 224 of a first collection container 221, a second opening 225 of a second collection container 222, a third opening 226 of a third collection container 223 which will be described later) when the treating liquid flows into the inlet.

The treating liquid collection module 220 may be configured to include a plurality of collection containers. The treating liquid collection module 220 may be configured to include, for example, three collection containers. When the treating liquid collection module 220 is configured to include the plurality of collection containers as described above, the module 220 may collect the substrate treating liquid used in the substrate treating process using the plurality of collection containers in an individual manner. Thus, recycling of the substrate treating liquid may be achieved.

When the treating liquid collection module 220 is configured to include the three collection containers, the module 220 may include the first collection container 221, the second collection container 222, and the third collection container 223. Each of the first collection container 221, the second collection container 222, and the third collection container 223 may be implemented as, for example, a bowl.

The first collection container 221, the second collection container 222, and the third collection container 223 may collect different types of the substrate treating liquids. For example, the first collection container 221 may collect water, and the second collection container 222 may collect a first chemical liquid (e.g., one of a substance containing the IPA component and a substance containing the SPM component), and the third collection container 223 may collect a second chemical liquid (e.g., the other of the substance containing the IPA component and the substance containing the SPM component).

The first collection container 221, the second collection container 222, and the third collection container 223 may be respectively connected, at bottom faces thereof, to first to third collection lines 227, 228, and 229 extending downwardly (in a third direction 30). A first treating liquid, a second treating liquid, and a third treating liquid respectively collected through the first collection container 221, the second collection container 222 and the third collection container 223 may be treated to be reusable via a treating liquid recycling system (not shown).

Each of the first collection container 221, the second collection container 222 and the third collection container 223 may be formed in an annular ring shape surrounding the substrate support module 210. A relationship between sizes in a second direction 20 of the first collection container 221, the second collection container 222, and the third collection container 223 may be as follows: the first collection container 221<the second collection container 222<the third collection container 223. When a spacing between the first collection container 221 and the second collection container 222 is defined as a first spacing, and a spacing between the second collection container 222 and the third collection container 223 is defined as a second spacing, the first spacing may be equal to the second spacing. However, the present embodiment is not limited thereto. In another example, the first spacing is different from the second spacing. That is, the first spacing may be greater than the second spacing, or may be smaller than the second spacing.

The lift module 230 linearly moves the treating liquid collection module 220 in the vertical direction, that is, in the third direction 30. Thus, the lift module 230 may serve to adjust a relative vertical level of the treating liquid collection module 220 with respect to the substrate support module 210 (or the substrate W).

The lift module 230 may be configured to include a bracket 231, a first support shaft 232 and a first driver 233.

The bracket 231 is fixed to an outer wall of the treating liquid collection module 220. The bracket 231 may be coupled to the first support shaft 232 that moves up and down under an operation of the first driver 233.

When the substrate W is seated on the substrate support module 210, the substrate support module 210 may be positioned above the treating liquid collection module 220. Similarly, even when the substrate W is detached from the substrate support module 210, the substrate support module 210 may be positioned above the treating liquid collection module 220. In this case, the lift module 230 may serve to lower a vertical level of the treating liquid collection module 220.

When the treating process for the substrate W is in progress, the treating liquid may be collected to one of the first collection container 221, the second collection container 222, and the third collection container 223 according to a type of the substrate treating liquid ejected onto the substrate W. Even in this case, the lift module 230 may serve to elevate the treating liquid collection module 220 to a corresponding position. For example, when the first treating liquid is used as the substrate treating liquid, the lift module 230 may lift the treating liquid collection module 220 so that the substrate W is positioned at a vertical level corresponding to the first opening 224 of the first collection container 221.

In one example, in this embodiment, the lift module 230 linearly moves the substrate support module 210 up and down to adjust the relative vertical level of the treating liquid collection module 220 with respect to the substrate support module 210 or the substrate W.

However, the present embodiment is not limited thereto. The lift module 230 may linearly move the substrate support module 210 and the treating liquid collection module 220 up and down at the same time to adjust the relative vertical level of the treating liquid collection module 220 with respect to the substrate support module 210 or the substrate W.

The spray module 240 supplies the substrate treating liquid on the substrate W when treating the substrate W. At least one spray module 240 may be installed in a substrate treating apparatus 110. When a plurality of spray modules 240 are installed in the substrate treating apparatus 110, the spray modules 240 may spray different substrate treating liquids onto the substrate W.

The spray module 240 may be configured to include a nozzle 241, a nozzle support 242, a second support shaft 243, and a second driver 244.

The nozzle 241 is installed at an end of the nozzle support 242. This nozzle 241 may move to a process position or a standby position under an operation of the second driver 244.

In the above description, the process position refers to a position above the substrate W, and the standby position refers to a remaining area except for the process position. The nozzle 241 may move to the process position when ejecting the substrate treating liquid onto the substrate W. After ejecting the substrate treating liquid onto the substrate W, the nozzle 241 may leave the process position and move to the standby position.

The nozzle support 242 is configured to support the nozzle 241. The nozzle support 242 may be formed to extend in a direction corresponding to a longitudinal direction of the spin head 211. That is, the nozzle support 242 may has a longitudinal direction extending along the second direction 20.

The nozzle support 242 may be coupled to the second support shaft 243 extending in a direction perpendicular to the longitudinal direction of the nozzle support 242. The second support shaft 243 may be formed to extend to reach a vertical level corresponding to a vertical level of the spin head 211. That is, the longitudinal direction of the second support shaft 243 may be the third direction 30.

The second driver 244 rotates and elevates the second support shaft 243 and the nozzle support 242 linked with the second support shaft 243. Due to this function of the second driver 244, the nozzle 241 may move to the process position or the standby position.

Reference to FIG. 1 will be made again for following descriptions.

The substrate treating liquid supply 120 provides the substrate treating liquid to the apparatus 110 for treating the substrate. For this purpose, the substrate treating liquid supply 120 may be connected to the spray module 240 of the apparatus 110 for treating the substrate, and may operate under control of the controller 130.

The controller 130 controls an operation of the apparatus 110 for treating the substrate. Specifically, the controller 130 may control an operation of each of the rotation driver 213 of the substrate support module 210, the first driver 233 of the lift module 230, and the second driver 244 of the spray module 240.

The controller 130 may be implemented as a computer or a server including a process (e.g., a microprocessor) having a computing function or a control function, a memory with a storage function, a power supply with a power supply function, etc. In this embodiment, the controller 130 may be embodied as a processor.

In one example, the controller 130 may control the operation of the substrate treating liquid supply 120 so that the substrate treating liquid may be supplied from the substrate treating liquid supply 120 to the apparatus 110 for treating the substrate when necessary.

Next, a recipe that may increase an absorption amount of metal ions on the substrate will be described.

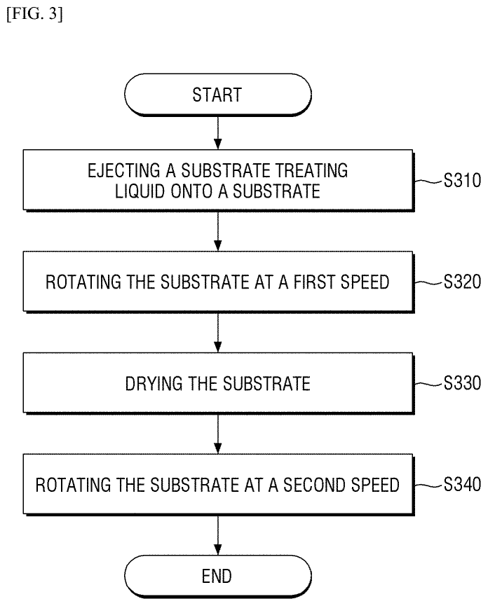

FIG. 3 is a flowchart sequentially illustrating a method for treating a substrate using an apparatus for treating a substrate according to an embodiment of the present disclosure. Reference to FIG. 3 will be made for following descriptions.

When the substrate treating liquid has deteriorated or a problem occurs in the nozzle ejecting the substrate treating liquid, metal ions contained in the substrate treating liquid may be detected on the substrate W when cleaning the substrate W.

However, when the substrate W is cleaned according to a conventional recipe, there is a problem in that the absorption amount of the metal ions into the substrate W is small because a residence time of the substrate treating liquid on the substrate W is short. Therefore, even when the substrate treating liquid has deteriorated or the problem has occurred in the nozzle, this deterioration or the problem may not be properly detected in an inspection process.

A recipe according to the present embodiment is characterized to increase the absorption amount of the metal ions on the substrate W in order to solve the above problem.

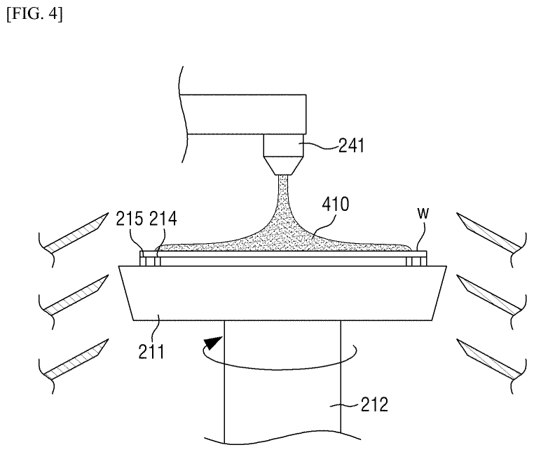

First, when the substrate W is seated on and fixed to the substrate support module 210, the spray module 240 ejects the substrate treating liquid 410 onto the substrate W in S310, and the substrate support module 210 rotates at a first rotation speed such that the substrate W may rotate in S320, as shown in FIG. 4.

In the above description, the substrate treating liquid ejection from the spray module 240 in S310 may be performed simultaneously with the rotation of the substrate support module 210 in S320. However, the present embodiment is not limited thereto. In this embodiment, the substrate treating liquid ejection from the spray module 240 in S310 may be performed prior to the rotation of the substrate support module 210 in S320. FIG. 4 is a first illustrative diagram for illustrating a method for treating a substrate according to an embodiment of the present disclosure.

As described above, the substrate support module 210 may rotate at the first rotation speed to rotate the substrate W when the spray module 240 ejects the substrate treating liquid 410 onto the substrate W. In this case, the first rotation speed may be a low-speed (or low RPM) lower than a first reference speed.

When the spray module 240 ejects the substrate treating liquid 410 onto the substrate W, and at the same time, the substrate support module 210 rotates at the first rotation speed lower than the first reference speed, the substrate treating liquid 410 is not easily bounced off from the substrate W due to the low-speed rotation of the substrate support module 210. This may increase the residence time of the substrate treating liquid 410 on the substrate W.

When the substrate treating liquid 410 is deteriorated, the substrate treating liquid 410 may contain the metal ions such as chromium (Cr). Therefore, when the residence time of the substrate treating liquid 410 on the substrate W is increased, the possibility that the metal ions in the substrate treating liquid 410 are adsorbed onto the substrate W may increase.

In the above description, the first reference speed refers to a general speed of the substrate support module 210 when treating the substrate W. The first reference speed may be, for example, in a range of 500 RPM to 800 RPM.

As described above, the first rotation speed of the substrate support module 210 may be lower than the first reference speed. In this embodiment, the first rotation speed of the substrate support module 210 may be set to the speed of the substrate treating liquid 410 at which the substrate treating liquid 410 is not bounced off from the substrate W when the substrate treating liquid ejection from the spray module 240 in S310 and the rotation of the substrate support module 210 in S320 are simultaneously performed. The first rotation speed may be, for example, in a range of 100 RPM to 300 RPM.

The first rotation speed of the substrate support module 210 may vary depending on a type of the substrate treating liquid 410. For example, when the substrate treating liquid 410 has a higher viscosity than a reference value, the first rotation speed of the substrate support module 210 may be higher (e.g., 200 RPM to 300 RPM) than a predetermined speed (e.g., 200 RPM) determined in consideration of the reference value. When the viscosity of the substrate treating liquid 410 is lower than the reference value, the first rotation speed of the substrate support module 210 may be lower, for example, 100 RPM to 200 RPM, than the predetermined speed, that is, 200 RPM.

In one example, the first rotation speed of the substrate support module 210 may maintain a constant value while the substrate treating liquid 410 is ejected onto the substrate W. However, the present embodiment is not limited thereto. The first rotation speed of the substrate support module 210 may vary within a certain range (that is, within a range of a speed at which the substrate treating liquid 410 is not bounced off from the substrate W to an outside).

The spray module 240 may eject the substrate treating liquid 410 onto the substrate W for a predetermined period of time. The spray module 240 may eject the substrate treating liquid 410 onto the substrate W for 30 seconds, in one example.

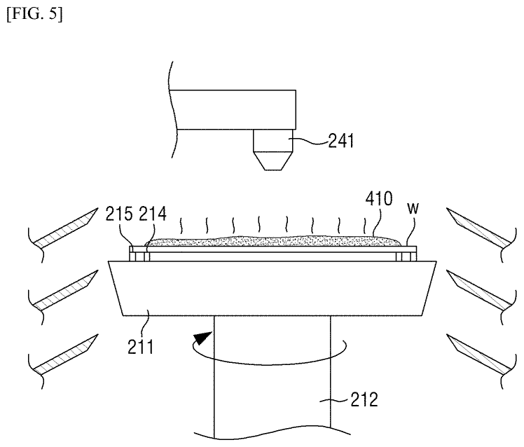

When the substrate treating liquid ejection from the spray module 240 in S310 is finished, a process of drying the substrate W may proceed. In this case, as shown in FIG. 5, the apparatus 110 for treating the substrate naturally dries the substrate W in S330, and the substrate support module 210 rotates at a second rotation speed to rotate the substate W in S340.

The drying of the substrate W in S330 and the rotation of substrate support module 210 in S340 may be continued until the substrate W is completely dried. Whether the substrate W is completely dried may be identified, for example, with a naked eye.

In the above description, the drying of the substrate W in S330 and rotation of the substrate support module 210 in S340 may be simultaneously performed when the substrate treating liquid ejection from the spray module 240 in S310 has been finished. However, the present embodiment is not limited thereto. In this embodiment, the drying of the substrate W in S330 may be performed before the rotation of the substrate support module 210 in S340, or may be performed later than the rotation of the substrate support module 210 in S340.

FIG. 5 is a second illustrative diagram for illustrating a method for treating a substrate according to an embodiment of the present disclosure.

In one example, in this embodiment, when drying the substrate W, the substrate support module 210 may not rotate. That is, S340 may be omitted and only S330 may be executed until the substrate W is completely dried.

As described above, the substrate support module 210 may rotate at the second rotation speed rotate to rotate the substrate W when drying the substrate W. In this case, in a similar manner to the first rotation speed, the second rotation speed may be a low-speed (or low RPM) lower than a second reference speed.

When drying the substrate W, the substrate support module 210 does not rotate or rotates at the second rotation speed lower than the second reference speed. This may minimize the bounce off of the substrate treating liquid 410 from the substate W to the outside, due to the non-rotation or the low-speed rotation of the substrate support module 210, compared to a case where the substrate support module 210 rotates at the second reference speed. Accordingly, a thickness of a liquid film on the substrate W may be increased, and the residence time of the substrate treating liquid 410 on the substrate W may be increased, thereby increasing the absorption amount of the metal ions on the substate W.

Further, only pure chemical is evaporated as the substrate treating liquid on the substrate W is dried along with the low-speed rotation of the substrate support module 210. Thus, the metal ions present in the chemical may remain on a surface of the substrate W, thereby increasing the possibility that the metal ions are detected.

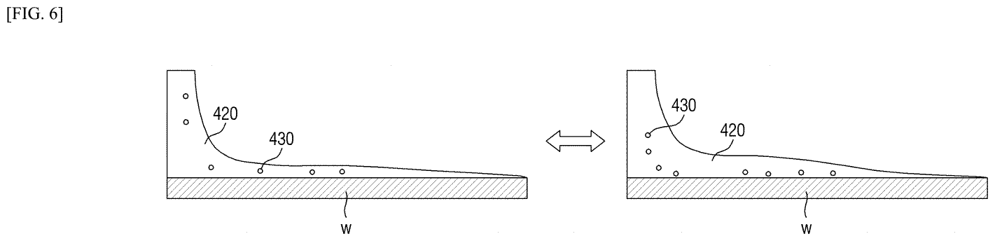

A left view in FIG. 6 shows a thickness of the liquid film 420 and the absorption amount of the metal ions (i.e., Cr) 430 when the substrate support module 210 rotates at the second reference speed. A right view in FIG. 6 shows the thickness of the liquid film 420 and the absorption amount of the metal ions 430 when the substrate support module 210 rotates at the second rotation speed lower than the second reference speed. FIG. 6 is an illustrative diagram for illustrating the difference between the conventional recipe and the present recipe according to the present disclosure.

In the above description, the second reference speed refers to a general speed of the substrate support module 210 when drying the substrate W. The second reference speed may be, for example, in a range of 1200 RPM to 1500 RPM.

In one example, as described above, the second rotation speed of the substrate support module 210 may be lower than the second reference speed. In this embodiment, the second rotation speed of the substrate support module 210 may be set such that, when the drying in S330 of the substrate W and the rotation in S340 of the substrate support module 210 are simultaneously performed, the substrate treating liquid 410 is not bounced off from the substrate W. The second rotation speed may be, for example, in a range of 100 RPM to 300 RPM.

The second rotation speed of the substrate support module 210 may vary depending on the type of the substrate treating liquid. For example, when the substrate treating liquid has a higher viscosity than the reference value, the second rotation speed of the substrate support module 210 may be higher (e.g., 200 RPM to 300 RPM) than the predetermined speed (e.g., 200 RPM) determined in consideration of the reference value. When the viscosity of the substrate treating liquid is lower than the reference value, the second rotation speed of the substrate support module 210 may be lower, for example, 100 RPM to 200 RPM than the predetermined speed, that is, 200 RPM.

In one example, the second rotation speed of the substrate support module 210 may maintain a constant value while the substrate W is naturally dried. However, the present embodiment is not limited thereto. The second rotation speed of the substrate support module 210 may vary within a certain range (that is, within a range of a speed at which the substrate treating liquid 410 is not bounced off from the substrate W to the outside).

In one example, before drying the sub state, pure water (DIW: De-Ionized Water) may be supplied onto the substrate W to additionally clean the substrate W.

The method for treating the substrate using the apparatus 110 for treating the substrate according to an embodiment of the present disclosure has been described above with reference to FIGS. 3 to 6. According to the method for treating the substrate using the apparatus 110 for treating the substrate, when the substrate treating liquid is provided on the substrate W, the substrate support module 210 may rotate at the first rotation speed to rotate the substrate W. Further, when drying the substrate W, the substrate support module 210 may rotate at the second rotation speed to rotate the substrate W.

The rotation speed of the substrate support module 210 when the substrate treating liquid is provided on the substrate W and the rotation speed of the substrate support module 210 when the substrate W is dried may be equal to each other. That is, in the present embodiment, the first rotation speed and the second rotation speed may have the same value.

However, the present embodiment is not limited thereto. The rotation speed of the substrate support module 210 when the substrate treating liquid is provided on the substrate W and the rotation speed of the substrate support module 210 when the substrate W is dried may be different from each other.

In one example, in order to prevent the metal ions from being removed from the substrate W when drying the substrate W, the rotation speed of the substrate support module 210 when drying the substrate W may be lower than the rotation speed of the substrate support module 210 when providing the substrate treating liquid on the substrate W. That is, in this embodiment, the second rotation speed may be lower than each of the first rotation speed and the second reference speed (the second rotation speed<the first rotation speed<the second reference speed).

The rotation speed of the substrate support module 210 when the substrate treating liquid is provided on the substrate W and the rotation speed of the substrate support module 210 when the substrate W is dried may be equal to each other. In this case, it may take a longer time to completely dry the substrate W. Therefore, in this embodiment, taking this fact into consideration, the rotation speed of the substrate support module 210 when drying the substrate W may be higher than the rotation speed of the substrate support module 210 when providing the substrate treating liquid on the substrate W. That is, in this embodiment, the second rotation speed may be lower than the second reference speed, but may be higher than the first rotation speed (first rotation speed<second rotation speed<second reference speed).

Next, an inspection process of the substrate W will be described. The inspection process of the substrate W to be described below may be performed after the substrate W has been completely dried through S310 to S340 in FIG. 3.

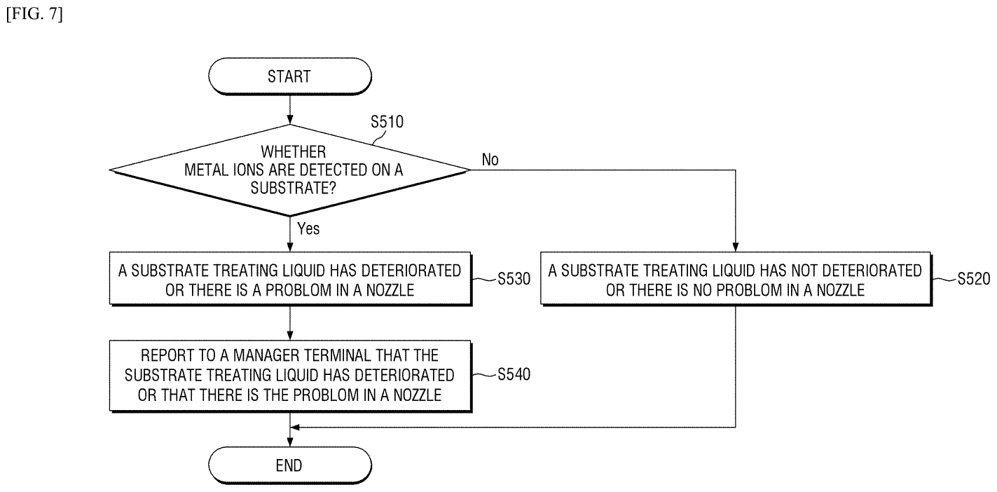

FIG. 7 is a flowchart for sequentially illustrating a method for treating a substrate after drying a substrate. Reference to FIG. 7 will be made for the following descriptions. The method of FIG. 7 may be performed by a separately provided substrate inspection apparatus (not shown).

When the substrate W has been completely dried, the substrate W may move to a place where the substrate inspection apparatus is positioned. When the substrate W reaches the destination, the substrate inspection apparatus determines whether or not the metal ions are detected on the substrate W in S510.

When no metal ions are detected on the substrate W, the substrate inspection apparatus determines that the substrate treating liquid has not deteriorated, and that there is no problem in the nozzle for ejecting the substrate treating liquid in S520.

On the contrary, when the metal ion is detected on the substrate W, the substrate inspection apparatus determines that the substrate treating liquid has deteriorated or that there is the problem in the nozzle in S530.

Thereafter, the substrate inspection apparatus reports to a manager terminal that the substrate treating liquid has deteriorated or that there is the problem in the nozzle in S540.

With reference to FIGS. 1 to 7, the substrate treating system 100 and the method for treating the substrate according to an embodiment of the present disclosure have been described above. The present disclosure relates to a natural drying recipe for metal ion detection. The conventional recipe has a problem in that the metal ions are not absorbed on the substrate. However, the recipe according to the present disclosure is an improved recipe for metal ion detection, and has a higher detection possibility of the metal ions on the substrate than that of the conventional recipe.

An order (based on chemicals) at which the recipe according to the present disclosure proceeds is summarized as follows.

\textcircled{1}200 rpm Spin+Chemical Dispense 30 s

\textcircled{2}200 rpm Spin Dry 360 s (based on SC-1, until the chemical is completely dried)

\textcircled{3}0 rpm Process Done

The recipe according to the present disclosure may achieve following effects through the above-described procedure.

First, ejecting the chemical onto the surface of the substrate W at the low RPM may allow the residence time of the chemical on the substate to be increased, thereby increasing the absorption amount of the metal ions in the chemical onto the surface of the substate.

Second, the low RPM drying may increase the residence time of the chemicals on the surface of the substrate W to increase the absorption amount of the metal ions on the surface of the substrate, and to achieve analysis of the metal ions in the chemical.

Although the embodiments of the present disclosure have been described with reference to the above descriptions and the accompanying drawings, those of ordinary skill in the art to which the present disclosure pertains may appreciate that the present disclosure may be practiced in another specific form without changing its technical idea or essential characteristics. Therefore, it should be understood that the embodiments as described above are illustrative and not restrictive in all respects.

What is claimed is:

1. A method for treating a substrate, the method comprising:
ejecting a substrate treating liquid onto the substrate;
rotating the substrate at a first speed; and
when the ejecting of the substrate treating liquid has been finished, drying the substrate.

2. The method of claim 1, wherein the method for treating the substrate is performed when inspecting the substrate treating liquid, and/or inspecting a nozzle for ejecting the substrate treating liquid.

3. The method of claim 1, wherein the method further comprises rotating the substrate at a second speed,
wherein rotating the substrate at the second speed is performed simultaneously with or before or after the drying of the substate.

4. The method of claim 1, wherein the first speed is set to a speed at which the substrate treating liquid is not bounced off from the substrate.

5. The method of claim 1, wherein the first speed is lower than a first reference speed.

6. The method of claim 5, wherein the first reference speed is a rotation speed when the substrate is generally treated.

7. The method of claim 1, wherein the first speed is constant while the substrate treating liquid is ejected.

8. The method of claim 1, wherein the drying of the substrate includes naturally drying the substrate.

9. The method of claim 1, wherein the drying of the substrate includes drying the substrate while the substrate does not rotate.

10. The method of claim 1, wherein the ejecting of the substrate treating liquid is performed simultaneously with the rotating of the substate at the first speed, or is performed before the rotating the substrate at the first speed.

11. The method of claim 3, wherein the second speed is equal to or lower than the first speed.

12. The method of claim 1, wherein the first speed is 200 RPM.

13. The method of claim 1, wherein the first speed varies depending on viscosity of the substrate treating liquid.

14. The method of claim 1, wherein the method further comprises:
when the substrate has been dried, determining whether metal ions are detected on the substrate; and
inspecting whether a defect occurs in a nozzle for ejecting the substrate treating liquid and/or the substrate treating liquid is deteriorated, based on the determination result related to the metal ions.

15. The method of claim 14, wherein the inspecting includes determining that when the metal ions are detected on the substrate, the substrate treating liquid has been deteriorated and/or the defect has occurred in the nozzle.

16. A method for treating a substrate, the method comprising:
ejecting a substrate treating liquid onto the substrate;
rotating the substrate at a first speed;
when the ejecting of the substrate treating liquid has been finished, drying the substrate; and
rotating the substrate at a second speed;
wherein each of the first speed and the second speed is set to a speed at which the substrate treating liquid is not bounced off from the substrate.

17. An apparatus for treating a substrate, the apparatus comprising:
a substrate support module for supporting the substrate; and
a spray module for ejecting a substrate treating liquid onto the substrate,
wherein the substrate support module is configured to rotate the substrate at a first speed when the spray module ejects the substrate treating liquid onto the substrate;
wherein the apparatus is configured to dry the substrate when the ejecting of the substrate treating liquid has been finished.

18. The apparatus of claim 17, wherein the substrate support module is configured to rotate the substrate at the first speed when the substrate treating liquid, and/or a nozzle for ejecting the substrate treating liquid is inspected.

19. The apparatus of claim 17, wherein the substrate support module is configured not to rotate the substrate or to rotate the substrate at a second speed when the apparatus dries the substrate.

20. The apparatus of claim 19, wherein the second speed is lower than or equal to the first speed.
